(19) United States
(12) Patent Application Publication
(10) Pub. No.: US 2016/0005897 A1
(43) Pub. Date: Jan. 7, 2016

(54) ELECTRONIC COMPONENT AND MANUFACTURING METHOD THEREOF

(71) Applicant: YOUTEC CO., LTD., Chiba (JP)

(72) Inventors: Yuuji HONDA, Chiba (JP); Kohei OKUDAIRA, Chiba (JP); Yukari MIKAMI, Chiba (JP)

(21) Appl. No.: 14/754,903

(22) Filed: Jun. 30, 2015

(30) Foreign Application Priority Data
Jul. 2, 2014 (JP) 2014-137011

(51) Int. Cl. H01L 31/048; H01L 27/146; H01L 31/0216; H01L 31/0368; H01L 31/0376

(52) U.S. Cl. CPC H01L 31/048; H01L 31/03685; H01L 31/03762; H01L 31/0216; H01L 27/1462; H01L 27/14685

(57) ABSTRACT

To provide an electronic component having a protective film formed with a good uniformity, over the entire surface thereof. An aspect of the present invention is an electronic component having a protective film formed over the entire surface thereof, the electronic component has elements and wirings formed on a base body, and the protective film has been formed by a CVD method, over an entire surface of said electronic component, by: arranging an electrode in a chamber; grounding one side of the chamber and the electrode; accommodating the electronic component in the chamber; supplying an raw material gas to the chamber; rotating or swinging the chamber and thereby moving the electronic component in the chamber; supplying high-frequency power to the other side of the chamber and the electrode; and generating a raw-material-gas-based plasma between the electrode and the chamber.

### BACKGROUND OF THE INVENTION

1. Field of the Invention

The invention relates to an electronic component and a manufacturing method thereof.

2. Description of a Related Art

When manufacturing an electronic component, it maybe required to remove the oxidized film or the like covering the surface of the electronic component by etching, and form a protective film over the entire surface of the electronic component in order to protect the surface of electronic component.

However, when the size of the electronic component is very small, it is difficult to etch the entire surface of the electronic component with a good uniformity and form a protective film over the entire surface of the electronic component with a good uniformity.

### SUMMARY OF THE INVENTION

### Problems to be Solved by the Invention

An aspect of the invention is to provide an electronic component whose entire surface has been etched with a good uniformity, or a method of manufacturing the same.

In addition, an aspect of the invention is to provide an electronic component having a protective film formed over the entire surface thereof with a good uniformity, or a method of manufacturing the same.

### Means to Solve the Problems

In the following, various embodiments of the invention will be described.
[1] An electronic component having a protective film formed over the entire surface thereof,

wherein the electronic component has elements and wirings formed on a base body,

wherein the protective film has been formed by a CVD method, over an entire surface of the electronic component, by: arranging an electrode in a chamber; grounding one side of the chamber and the electrode; accommodating the electronic component in the chamber; supplying raw material gas to the chamber; rotating or swinging the chamber and thereby moving the electronic component in the chamber; supplying high-frequency power to the other side of the chamber and the electrode; and generating a raw-material-gas-based plasma between the electrode and the chamber.

Note that preferably, the chamber has a circular or polygonal shape of the internal cross-section substantially parallel to the direction of gravity, and the rotational axis when rotating or swinging the chamber is substantially perpendicular to the cross-section.
[2] An electronic component having a protective film formed over the entire surface thereof,

wherein the electronic component has elements and wirings formed on a base body,

wherein the protective film has been formed by a CVD method, over an entire surface of the electronic component, by: arranging, in a chamber, a container having a circular or polygonal shape of an internal cross-section; providing an electrode in the container; grounding one side of the container and the electrode; accommodating the electronic component in the container; supplying raw material gas to the container; rotating or swinging the container around a direction substantially perpendicular to the cross-section as a rotational axis and thereby moving the electronic component in the container; supplying high-frequency power to the other side of the container and the electrode; and generating a raw-material-gas-based plasma between the electrode and the container.

Note that, preferably, a frequency of the high-frequency power is in a range of 10 kHz to 1 MHz.
[3] An electronic component having a protective film formed over the entire surface thereof,

wherein the electronic component has elements and wirings formed on a base body,

wherein the protective film has been formed over an entire surface of the electronic component by: accommodating the electronic component in a chamber having a circular or polygonal shape of an internal cross-section; rotating or swinging the chamber round a direction substantially perpendicular to the cross-section as a rotational axis and thereby performing sputtering while stirring or rotating the electronic component in the chamber.
[4] The electronic component of one of the items [1] to [3], wherein the element is an optical sensor.
[5] The electronic component according to any one of the items [1] to [3], wherein the element is a solar cell element.
[6] The electronic component according to the item [5], wherein the base body contains amorphous silicon or polycrystalline silicon.
[7] A method of manufacturing an electronic component, including the steps of: arranging an electrode in a chamber; grounding one side of the chamber and the electrode; accommodating, in the chamber, an electronic component having elements and wirings formed on a base body; supplying raw material gas to the chamber; rotating or swinging the chamber and thereby moving the electronic component in the chamber; supplying high-frequency power to the other side of the chamber and the electrode; and generating a raw-material-gas-based plasma between the electrode and the chamber to thereby form a protective film over an entire surface of the electronic component, by a CVD method.
[8] The method of manufacturing an electronic component according to the item [7], including the steps of: supplying an etching gas to the chamber before supplying a raw material gas to the chamber; etching an entire surface of the electronic component by generating an etching gas-based plasma between the electrode and the chamber and then terminating supply of the etching gas to the chamber; and supplying the raw material gas to the chamber.

Note that preferably, the chamber has a circular or polygonal shape of the internal cross-section substantially parallel to the direction of gravity, and the rotational axis when rotating or swinging the chamber is substantially perpendicular to the cross-section.
[9] A method of manufacturing an electronic component, comprising the steps of: arranging in a chamber a container having a circular or polygonal shape of an internal cross-section; arranging an electrode in the container; grounding one side of the container and the electrode; accommodating, in the container, the electronic component having elements and wirings formed on a base body; supplying a raw material gas to the container; rotating or swinging the container around a direction substantially perpendicular to the cross-section as a rotational axis and thereby moving the electronic component in the container; supplying high-frequency power to the other side of the container and the electrode; and generating a raw-material-gas-based plasma between the electrode and the container to thereby form a protective film over an entire surface of the electronic component, by a CVD method.
[10] The method of manufacturing an electronic component according to the item [9] comprising the steps of: supplying an etching gas to the container before supplying a raw material gas to the container; etching the entire surface of the electronic component by generating an etching gas-based plasma between the electrode and the container and then terminating supply of the etching gas to the container; and supplying the raw material gas to the container.
[11] The method of manufacturing an electronic component according to any one of the items [7] to [10], wherein a frequency of the high-frequency power is in a range of 10 kHz to 1 MHz.
[12] The method of manufacturing an electronic component according to any one of the items [7] to [11], wherein the element is an optical sensor.
[13] The method of manufacturing an electronic component according to any one of the items [7] to [11], wherein the element is a solar cell element.
[14] The method of manufacturing an electronic component according to the item [13], wherein the base body contains amorphous silicon or polycrystalline silicon.

### Effects of the Invention

According to an aspect of the invention, there can be provided an electronic component having the entire surface thereof been etched with a good uniformity, or a method of manufacturing the same.

Furthermore, according to another aspect of the invention, there can be provided an electronic component having a protective film been formed with a good uniformity over the entire surface thereof, or a method of manufacturing the same.

### BRIEF DESCRIPTION OF THE DRAWINGS

FIG. 1A is a schematic view illustrating a first photodetector of an exemplary electronic component according to an aspect of the invention, and FIG. 1B is a schematic view illustrating a second photodetector of an exemplary electronic component according to an aspect of the invention;

FIG. 2A is a schematic view illustrating a ball-shaped solar cell of an exemplary electronic component according to an aspect of the invention, and FIG. 2B is a schematic view illustrating a state of arranging a plurality of the ball-shaped solar cells illustrated in FIG. 2A, on a substrate;

FIG. 3A is a plan view illustrating a semiconductor chip of an exemplary electronic component according to an aspect of the invention, and FIG. 3B is a cross-sectional view taken along the line 4B-4B illustrated in FIG. 3A;

FIG. 4A is a cross-sectional view illustrating a plasma processing apparatus for manufacturing an electronic component according to an aspect of the invention, and FIG. 4B is a cross-sectional view taken along the line 2-2 illustrated in FIG. 4A;

FIG. 5A is a cross-sectional view illustrating an outline of a plasma processing apparatus according to an aspect of the invention, and FIG. 5B is a cross-sectional view taken along the line 8B-8B illustrated in FIG. 5A;

FIG. 6 is a configuration diagram outlining a sputtering apparatus according to an aspect of the invention;

FIG. 7A is an FE-SEM image of a semiconductor chip before forming an SiO₂ film, and FIG. 7B is an FE-SEM image of the semiconductor chip after having formed the SiO₂ film;

FIG. 8 is a SIM image obtained by obtained by observing a cross-section of the semiconductor chip having formed thereon the protective film illustrated in FIG. 7B;

FIG. 9 is an experimental result obtained by examining whether or not the SiO₂ film on the semiconductor chip illustrated in FIG. 7B has sufficient insulation characteristics; and

FIG. 10 is an experimental result obtained by examining whether or not the SiO₂ film on the semiconductor chip illustrated in FIG. 7B has sufficient withstand voltage characteristics.

### DESCRIPTION OF THE PREFERRED EMBODIMENTS

Hereinafter, embodiments of the invention will be described in detail, using the drawings. However, a person skilled in the art would easily understand that the invention is not limited to the following description and the form and details can be variously modified without deviating from the gist and scope of the invention. Therefore, the invention should not be construed as being limited to the description of the embodiments shown below.

### Embodiment 1

<First Photodetector as Electronic Component>

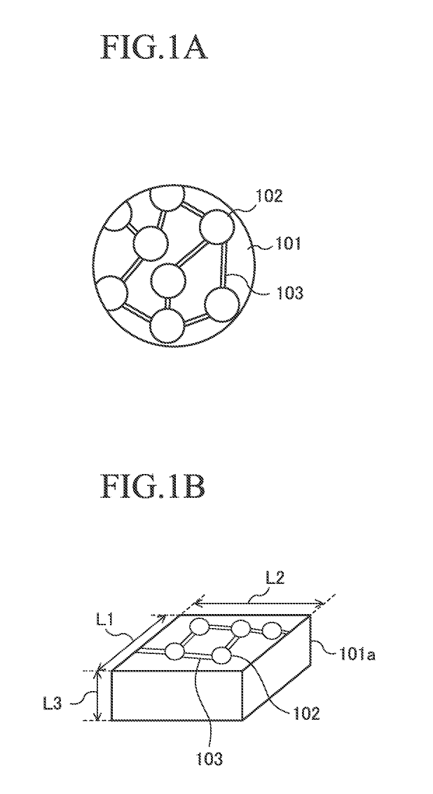

FIG. 1A is a schematic view illustrating a first photodetector of an exemplary electronic component according to an aspect of the invention. The first photodetector is a three-dimensional optical sensor, and the maximum external diameter thereof is preferably 50 mm or less, more preferably 5 mm or less. A plurality of elements 102 and a wiring 103 interconnecting the plurality of elements 102 are formed on a spherical base body 101. The elements 102 are optical sensors that detect electromagnetic energy of light. The wiring 103 includes, for example, a Cu film or a Cu alloy film.

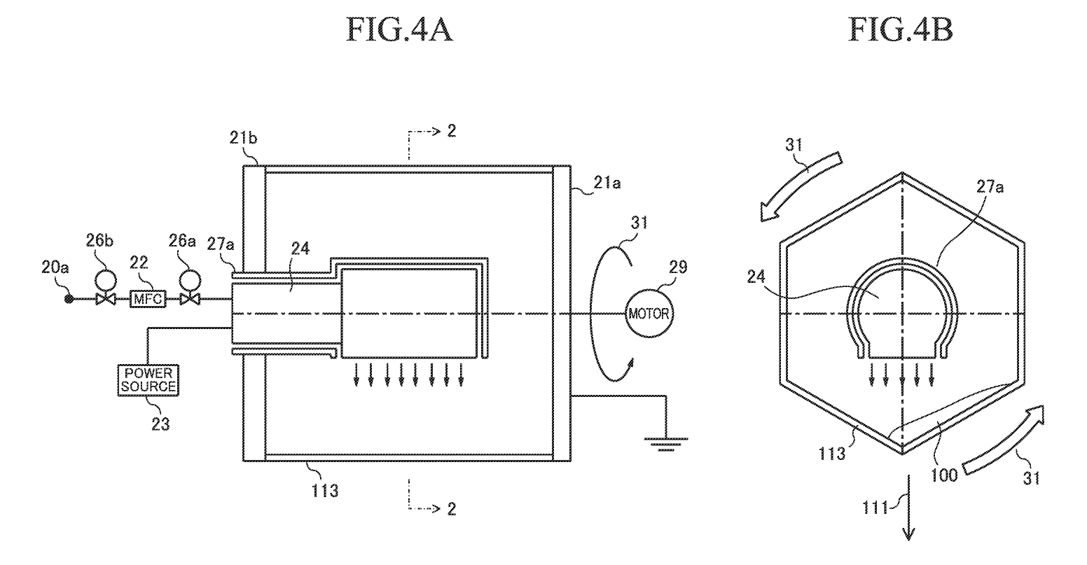

A protective film (not illustrated) is formed over the entire surface of the first photodetector. The protective film is a light-transmitting film that protects the entire surface of the first photodetector, and is also an insulation film such as an SiO₂ film. The protective film is a film formed by a plasma processing apparatus illustrated in FIG. 4, and has high insulation characteristics so as to sufficiently function as an insulation film. Specifically, the protective film is formed by a CVD method, over the entire surface of the first photodetector, by: arranging an electrode 24 in a chamber 113; grounding one side of the chamber 113 and the electrode 24; accommodating the first photodetector in the chamber 113; supplying a raw material gas to the chamber 113, rotating or swinging the chamber 113 and thereby moving the first photodetector in the chamber 113; supplying high-frequency power to the other side of the chamber 113 and the electrode 24; and generating a raw-material-gas-based plasma between the electrode 24 and the chamber 113.

<Second Photodetector as Electronic Component>

FIG. 1B is a schematic view illustrating a second photodetector of an exemplary electronic component according to an aspect of the invention, in which the same reference numerals are attached to the same parts as those in FIG. 1A, and only different parts will be described below.

The second photodetector has a base body 101a, and a plurality of elements 102 and a wiring 103 interconnecting the plurality of elements 102 are formed on the base body 101a. The base body 101a has a rectangular parallelepiped shape with a vertical length L₁, a horizontal length L₂, and a height L₃, where it is preferable that L₁ is 50 mm or less (preferably 5 mm or less), L₂ is 50 mm or less (preferably 5 mm or less), and L₃ is 40 mm or less (preferably 4 mm or less).

A protective film (not illustrated) is formed over the entire surface of the second photodetector. The protective film is similar to the protective film of the first photodetector illustrated in FIG. 1A.

<Ball-Shaped Solar Cell as Electronic Component>

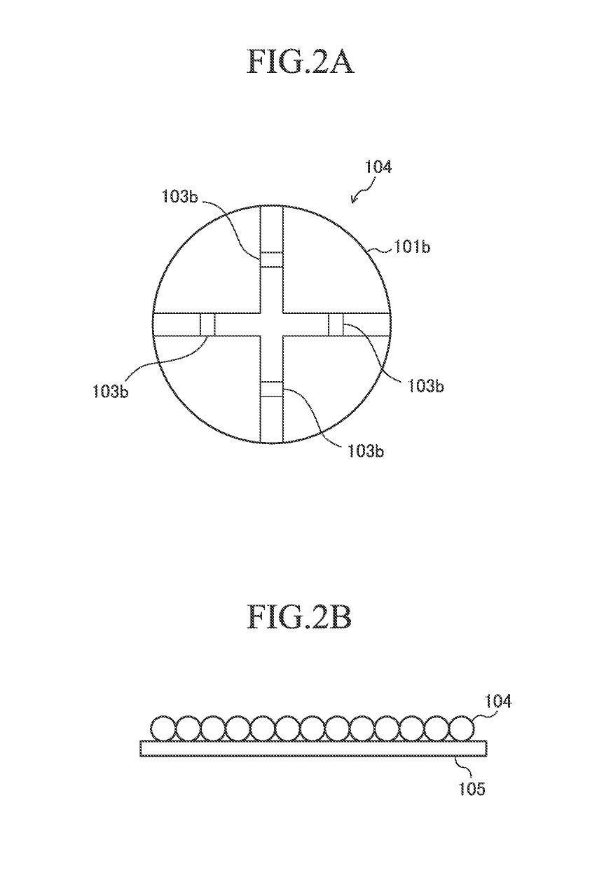

FIG. 2A is a schematic view illustrating ball-shaped solar cell 104 of an exemplary electronic component according to an aspect of the invention, and FIG. 2B is a schematic view illustrating a state of arranging a plurality of the ball-shaped solar cells 104 illustrated in FIG. 2A, on a substrate 105.

It is preferable that the maximum external diameter of the ball-shaped solar cell 104 illustrated in FIG. 2A is be 50 mm or less, more preferably 5 mm or less. The ball-shaped solar cell 104 has a spherical base body 101b, and the base body 101b has amorphous silicon or polycrystalline silicon. A solar cell element and a wiring 103b are formed on the base body 101b. The solar cell element converts light energy directly into electric power and outputs the converted power, through the utilization of the photovoltaic effect. The wiring 103b includes, for example, a Cu film or a Cu alloy film.

A protective film (not illustrated) is formed over the entire surface of the ball-shaped solar cell 104. The protective film is a light-transmitting film, and is similar to the protective film of the first photodetector illustrated in FIG. 1A.

A plurality of the above-described ball-shaped solar cells 104 is arranged on the substrate 105 as illustrated in FIG. 2B. Since the ball-shaped solar cell 104 is spherical, the surface area of the solar cell element per unit area on the substrate 105 can be increased in comparison with the case where the solar cell elements are planarly arranged on the substrate. Accordingly, it is possible to enhance the power generation effect per unit area on the substrate 105.

<Semiconductor Chip as Electronic Component>

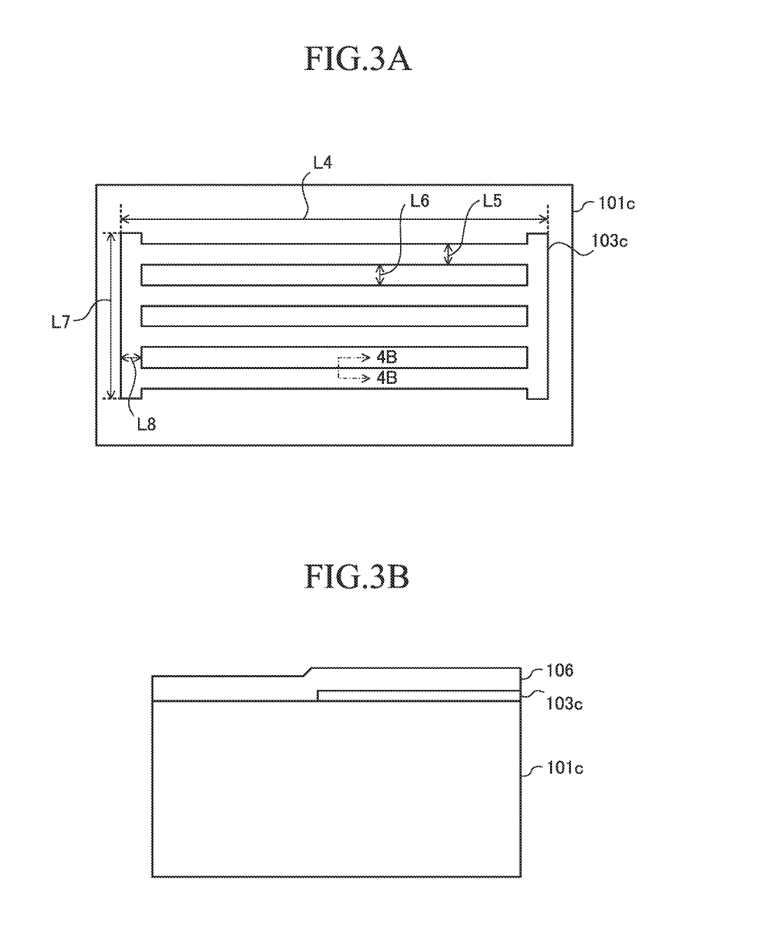

FIG. 3A is a plan view illustrating a semiconductor chip of an exemplary electronic component according to an aspect of the invention, and FIG. 3B is a cross-sectional view taken along the line 4B-4B illustrated in FIG. 3A.

The external dimensions of the semiconductor chip illustrated in FIG. 3A are 1000 μm long and 2000 μm wide. The semiconductor chip has a silicon substrate 101c as the base body, the silicon substrate 101c having a Cu wiring 103c formed thereon. The planar pattern dimensions of the Cu wiring 103c are: the horizontal line length L₄ being 1800 μm, the horizontal line width L₅ being 80 μm, the horizontal line space width L₆ being 80 μm, the vertical line length L₇ being 640 μm, and the vertical line width L₈ being 80 μm. Note that, although, in this aspect, the maximum external diameter of the semiconductor chip is set to be 2000 μm, semiconductor chips with other external diameters may be used if the maximum external diameter is 50 mm or less (preferably 5 mm or less). In addition, although the silicon substrate 101c is used as the base body in this aspect, other semiconductor substrates can also be used as the base body.

Details of the manufacturing method of the semiconductor chip are as follows.

As illustrated in FIG. 3B, a Cu wiring (Cu alloy wiring) 103c is formed on the silicon substrate 101c, by forming a Cu film (or a Cu alloy film) on the silicon wafer (silicon substrate 101c) by sputtering, and then by performing patterning of the Cu film (or the Cu alloy film). Next, the silicon wafer is cut into individual semiconductor chips (refer to FIG. 3A) by dicing.

Subsequently, a SiO₂ film 106 is formed over the entire surface of the semiconductor chip as a protective film. Specifically, the SiO₂ film 106 is formed on the Cu wiring 103c and the silicon substrate 101c by a CVD method.

Note that, in the present aspect, although the SiO₂ film 106 is formed as a protective film, a DLC (Diamond Like Carbon) film may be formed as a protective film.

The above-described protective film is a film formed by the plasma processing apparatus illustrated in FIG. 4, and has high insulation characteristics so as to sufficiently function as an insulation film. Specifically, the protective film is formed by a CVD method, over the entire surface of the semiconductor chip, by: arranging an electrode 24 in a chamber 113; grounding one side of the chamber 113 and the electrode 24; accommodating the semiconductor chip in the chamber 113; supplying a raw material gas to the chamber 113, rotating or swinging the chamber 113 and thereby moving the semiconductor chip in the chamber 113; supplying high-frequency power to the other side of the chamber 113 and the electrode 24; and generating a raw-material-gas-based plasma between the electrode 24 and the chamber 113.

<Plasma Processing Apparatus>

FIG. 4A is a cross-sectional view illustrating a plasma processing apparatus for manufacturing an electronic component according to an aspect of the invention, and FIG. 4B is a cross-sectional view taken along the line 2-2 illustrated in FIG. 4A.

The plasma processing apparatus is an apparatus for forming a thin film (protective film) over the entire surface of the electronic component by a CVD method, or for etching the entire surface of the electronic component.

As illustrated in FIGS. 4A and 4B, the plasma processing apparatus has a chamber 113 having a hexagonal internal cross-sectional shape. One end of the chamber 113 is closed by a chamber lid 21a, and the other end of the chamber 113 is closed by a chamber lid 21b. The chamber 113 and the chamber lids 21a and 21b are respectively connected to the ground (ground potential).

The interior of the chamber 113 accommodates an electronic component 100. The first photodetector illustrated in FIG. 1A, the second photodetector illustrated in FIG. 1B, the ball-shaped solar cell illustrated in FIG. 2, the semiconductor chip illustrated in FIG. 3, or the like, can be used as the electronic component 100.

The chamber 113 and the chamber lids 21a and 21b are respectively conductive. Note that, although the internal cross-sectional shape of the chamber 113 is assumed to be hexagonal barrel shape in the present embodiment, the internal cross-sectional shape of the chamber 113 may be any polygonal barrel shape other than a hexagon, and may be a barrel shape such as a pentagon, a heptagon, an octagon, a nonagon, a decagon, a hendecagon, or a dodecagon.

The cross-section illustrated in FIG. 4B is a cross-section substantially parallel to the direction of gravity 111. Note that the phrase “substantially parallel” used herein is meant to include directions deviated by ±3° from being completely parallel. In addition, the phrase “approximately perpendicular” used herein is meant to include directions deviated by ±3° from being completely perpendicular.

In addition, the plasma processing apparatus has a gas introduction mechanism configured to introduce a raw material gas or an etching gas into the chamber 113. The gas introduction mechanism has a cylindrical gas shower electrode (counter electrode) 21. The gas shower electrode 24 is arranged in the chamber 113. Namely, an aperture is formed on the chamber lid 21b of the other side of the chamber 113, and the gas shower electrode 24 is inserted from the aperture.

The gas shower electrode 24 is electrically connected to a power source 23, and thus high-frequency power is supplied to the gas shower electrode 24 from the power source 23. Preferably, a high-frequency power source having a frequency of 10 kHz to 1 MHz is used as the power source 23, and more preferably, a high-frequency power source having a frequency of 50 kHz to 500 kHz is used as the power source 23. The use of a power source of such a low frequency makes it possible to suppress plasma from dispersing outside the space between the gas shower electrode 24 and the chamber 113 in comparison with the case of using a power source of a frequency higher than 1 MHz. In other words, plasma can be confined between the gas shower electrode 24 and the chamber 113. The use of RF plasma in the range of 10 kHz to 1 MHz makes it difficult to cause induction heating in such a closed plasma space, and applies sufficient V_{DC} on the electronic component 100 when forming the film, and thus a protective film with a high hardness can be easily formed. In contrast, the use of RF plasma such as 13.56 MHz makes it difficult to form a protective film with a high hardness since it is difficult to apply V_{DC} on the electronic component 100 in a closed plasma space.

In addition, the case of applying high-frequency power having a frequency of 10 kHz-1 MHz to the gas shower electrode 24 and then grounding the chamber 113 accommodating the electronic component 100 allows a high-hardness protective film to be more easily formed on the surface of the electronic component 100 than the case of grounding the gas shower electrode 24 and then applying high-frequency power having a frequency of 10 kHz-1 MHz to the chamber 113 accommodating the electronic component 100. However, the configuration may be changed and implemented in such a manner as to ground the gas shower electrode 24 and then apply high-frequency power to the chamber 113.

The surface of the gas shower electrode (counter electrode) 24, other than the opposing surface facing the electronic component 100 accommodated in the chamber 113, is shielded with a ground shielding member 27a. The ground shielding member 27a and the gas shower electrode 24 have a gap of 5 mm or less (preferably 3 mm or less).

It is possible to concentrate the high-frequency power to the interior of the chamber 113 by covering the gas shower electrode 24 having high-frequency power supplied thereto with the ground shielding member 27a, with the result that it becomes possible to intensively supply high-frequency power to the electronic component 100 accommodated in the chamber 113.

The opposing surface on one side of the gas shower electrode 24 has a plurality of gas outlets configured to eject, in a shower-like state, one or more types of raw material gases or etching gases. The gas outlets are arranged at the bottom (the opposing surface) of the gas shower electrode 24 and are arranged so as to face the electronic component 100 accommodated in the chamber 113. Namely, the gas outlets are arranged so as to face the interior of the chamber 113.

In addition, as illustrated in FIG. 4B, the surface of the gas shower electrode 24 on the side opposite to the direction of gravity 111 has a convex shape toward the opposite side. Namely, the shape of the cross-section of the gas shower electrode 24 is circular or oval except for the bottom. Accordingly, even when the electronic component 100 happens to ride on the part supposed to be circular or oval (convex part) while the chamber 113 is being rotated, the electronic component 100 can be dropped from the gas shower electrode 24.

The other side of the gas shower electrode 24 is connected to one side of a mass flow controller (MFC) 22 via a vacuum valve 26a. The other side of the mass flow controller 22 is connected to a raw material gas source 20a or an etching gas source which is not illustrated, via the vacuum valve 26b or a filter which is not illustrated. The raw material gas source 20a generates different types of raw material gas depending on the protective film covering the electronic component 100, and is assumed to generate SiH₄ gas or the like when forming, for example, SiO₂ film.

Furthermore, the other side of the gas shower electrode 24 is connected, via a vacuum valve (not illustrated), to one side of the mass flow controller (MFC) which is not illustrated. The other side of the mass flow controller is connected to an argon gas cylinder (not illustrated).

A motor 29 as a rotation mechanism is provided in the chamber 113, and the film forming treatment or the etching treatment is performed while moving the electronic component 100 in the chamber 113 by rotating or swinging the chamber 113 by the motor 29 with the gas shower electrode 24 as a center of rotation, as indicated by the arrow 31 in FIGS. 4A and 4B. The axis of rotation when rotating the chamber 113 by the motor 29 is an axis which is parallel to the substantially horizontal direction (substantially perpendicular to the direction of gravity 111). Note that the phrase “substantially horizontal direction” used herein is meant to include directions deviated from the perfect horizontal direction by ±3°. In addition, the airtightness inside the chamber 113 is maintained even at rotation of the chamber 113.

Moreover, the plasma processing apparatus includes a vacuum exhaust mechanism that vacuum-exhausts the chamber 113. For example, a plurality of exhaust ports (not illustrated) is provided in the chamber 113, and is connected to a vacuum pump (not illustrated).

In addition, a grounding member, which is not illustrated, is provided in the chamber 113 so that a minimum diameter or minimum gap becomes 5 mm or less (preferably 3 mm or less) in the path through which gas is exhausted from the inside to the outside of the chamber 113 by the vacuum exhaust mechanism. The raw material gas introduced into the chamber 113 from the gas shower electrode 24 is exhausted from the exhaust port through the minimum diameter or minimum gap. At this time, setting the minimum diameter or minimum gap to be 5 mm or less makes it possible not to prevent the plasma from being confined in the vicinity of the electronic component 100 accommodated in the chamber 113. Namely, when the minimum diameter or minimum gap is set to be larger than 5 mm, dispersion of the plasma or abnormal electric discharge may be caused. To put it another way, setting the minimum diameter or minimum gap to be 5 mm or less makes it possible to suppress formation of a CVD film at the side of the exhaust port.

In addition, the gas shower electrode 24 has a heater (not illustrated). Additionally, the plasma processing apparatus may have a grounding rod (not illustrated) as a hitting member for applying vibration to the electronic component 100 accommodated in the interior of the chamber 113. Namely, the grounding rod may be constituted to hit the tip thereof against the chamber 113 by a drive mechanism (not illustrated). It becomes possible to apply vibration to the electronic component 100 accommodated in the chamber 113 by continuously hitting the grounding rod against the chamber 113. Accordingly, stirring of the electronic component 100 can be promoted.

Note that, although there is described in the present embodiment a plasma processing apparatus that accommodates the electronic component 100 in the chamber 113 having a hexagonal shape of an internal cross-section and that forms a thin film (protective film) on the electronic component 100, the shape of the internal cross-section of the chamber 113 is not limited to a hexagon and the internal cross-section of the chamber 113 may also be set to be circular or oval. The difference between the chamber 113 having a hexagonal shape of an internal cross-section and a chamber having a circular or oval shape of an internal cross-section lies in that the hexagonal chamber 113 allows a thin film (protective film) to be formed, with a good uniformity, over the entire surface of an electronic component having a smaller external diameter than a circular or oval chamber.

<Method of Manufacturing Electronic Component>

A method of forming a protective film on the electronic component 100 by using the plasma processing apparatus illustrated in FIG. 4 will be described. Here, there will be described an exemplary method of using, as the electronic component 100, the first photodetector illustrated in FIG. 1A, the second photodetector illustrated in FIG. 1B, the ball-shaped solar cell illustrated in FIG. 2, the semiconductor chip illustrated in FIG. 3, or the like, and of using a protective film (e.g., SiO₂ film, DLC film, etc.) on the electronic component 100.

First, a plurality of the electronic components 100 is accommodated in the chamber 113. The maximum external diameter of each of the electronic components 100 is 50 mm or less (preferably 5 mm or less).

Subsequently, the interior of the chamber 113 is decompressed to a predetermined pressure (e.g., approximately 5×10⁻⁵ Torr) by operating a vacuum pump. At the same time, the rotation of the chamber 113 by the motor 29 causes the electronic component 100 accommodated within the chamber 113 to move on the internal surface of the chamber. Note that, although the chamber 113 is being rotated here, it is also possible to swing the chamber 113 by using the rotation mechanism.

Next, toluene (C₇H₈), for example, is generated as the raw material gas in the raw material gas source 20a, the flow rate of toluene being controlled to be 7 cc/minute and the flow rate of argon gas supplied from an argon gas cylinder being controlled to be 5 cc/minute by the mass flow controller 22, and the flow-rate-controlled toluene gas and argon gas are introduced into the interior of the gas shower electrode 24. Then, the toluene gas and the argon gas are ejected from the gas outlets of the gas shower electrode 24. Accordingly, the toluene gas and the argon gas are sprayed on the electronic component 100 rotationally moving in the chamber 113, and the interior of the chamber 113 is maintained at a pressure suitable for film formation by CVD due to the balance between the controlled gas flow rate and the exhaust capacity. Note that, although toluene is used as raw material gas in the present aspect, the raw material gas may be modified as appropriate according to the material of the protective film.

In addition, the grounding rod is continuously hit against the rotating chamber 113 by the drive mechanism. Accordingly, it is possible to apply vibration to the electronic component 100 accommodated in the chamber 113, and promote stirring and mixing of the electronic components 100.

Subsequently, an RF output of 250 kHz at 150 W is supplied from the power source 23 to the gas shower electrode 24. Here, the chamber 113 and the electronic component 100 are connected to the ground. Accordingly, plasma is ignited between the gas shower electrode 24 and the chamber 113 to generate plasma in the chamber 113, whereby a protective film including DLC is formed over the entire surface of the electronic component 100. Namely, the electronic component 100 is stirred and rotated by rotating the chamber 113, and thus formation of the protective film uniformly over the entire surface of the electronic component 100 is facilitated.

According to the above-described embodiment, the apparatus configuration of applying high-frequency power to the gas shower electrode 24 and then grounding the chamber 113 accommodating the electronic component 100 makes it possible to further simplify the mechanical structure of the plasma processing apparatus and reduce the apparatus cost in comparison with the case of grounding the gas shower electrode 24 and subsequently applying high-frequency power to the chamber 113. In addition, the simplified mechanical structure of the plasma processing apparatus results in an increased maintainability.

In addition, in the present embodiment, the apparatus configuration of applying high-frequency power to the gas shower electrode 24 makes it possible to easily perform matching and to make out-of-tuning difficult to be generated, in comparison with the case of applying high-frequency power to the chamber 113. This is because, with the configuration of applying high-frequency power to the chamber 113, the impedance usually changes by rotation of the chamber 113, with the result that it becomes difficult to perform matching and the out-of-tuning is easily generated.

Additionally, in the present embodiment, rotation of the hexagonal-barrel-shaped chamber 113 itself allows the electronic component 100 itself to be rotated and stirred, and the hexagonal shape of the barrel further allows the electronic component 100 to regularly drop by gravity. Accordingly, the stirring efficiency can be drastically enhanced. Therefore, it becomes possible to form a protective film on the electronic component 100 having a very small external diameter. Specifically, it becomes possible to form a protective film over the entire surface of an electronic component having a maximum external diameter of 50 mm or less (preferably, electronic component having a maximum external diameter of 5 mm or less).

Additionally, in the present embodiment, the surface of the gas shower electrode 24 is shielded with the ground shielding member 27a except for the opposing surface facing the electronic component 100 accommodated in the chamber 113. Accordingly, it is possible to generate plasma between internal surface of the chamber 113 and the gas shower electrode 24 facing thereto. Namely, the high-frequency output can be concentrated inside the chamber 113, and as a result, high-frequency power can be intensively supplied to the electronic component 100 accommodated in the interior of the chamber 113, whereby high-frequency power can be effectively supplied to the electronic component 100.

Additionally, in the present embodiment, stirring of the electronic component 100 accommodated in the chamber 113 can be promoted by continually hitting the grounding rod against the chamber 113. Therefore, it becomes possible to also cover, with a good uniformity, the electronic component 100 having a smaller maximum external diameter, with a protective film including DLC.

Note that, in the above-described embodiment, although plasma CVD of forming a protective film including DLC on the electronic component 100 is described, a plasma processing apparatus according to the present embodiment can be used for forming a protective film including materials other than DLC on the electronic component 100.

In addition, in the above-described embodiment, as to the formation of the protective film over the entire surface of the electronic component 100, the protective film may be formed over the entire surface of the electronic component 100 after having etched the entire surface of the electronic component 100 and having removed an unnecessary insulation film or the like, before forming the protective film over the entire surface of the electronic component 100. In this case, details of the manufacturing method will be given as follows.

An etching gas is generated in the etching gas source, the etching gas is controlled to be a predetermined flow rate by the mass flow controller 22, and the flow-rate-controlled etching gas is introduced into the interior of the gas shower electrode 24. Then, the etching gas is then ejected from the gas outlets of the gas shower electrode 24. Accordingly, the etching gas is sprayed on the electronic component 100 rotationally moving in the chamber 113, and the interior of the chamber 113 is kept at a pressure suitable for etching due to the balance between controlled gas flow rate and the exhaust ability.

Subsequently, an RF output of 250 kHz at 150 W is supplied from the power source 23 to the gas shower electrode 24. In this case, the chamber 113 and the electronic component 100 are grounded. Accordingly, plasma is ignited between the gas shower electrode 24 and the chamber 113, and plasma is generated in the chamber 113, with the result that the entire surface of the electronic component 100 is etched.

Next, a protective film is formed over the entire surface of the electronic component 100 by a method similar to the above-described method of forming the protective film by terminating supply of an etching gas, generating a raw material gas in the raw material gas source 20a, controlling the flow rate of the raw material gas by the mass flow controller 22, controlling the flow rate of argon gas supplied from the argon gas cylinder, and introducing the flow-rate-controlled gas into the interior of the gas shower electrode 24.

### Embodiment 2

<First Photodetector as Electronic Component>

The first photodetector of an exemplary electronic component according to an aspect of the invention has an element 102 and a wiring 103 formed on the base body 101 as illustrated in FIG. 1A. A protective film (not illustrated) is formed over the entire surface of the first photodetector. The protective film is a film formed by the plasma processing apparatus illustrated in FIG. 5, and has high insulation characteristics so as to sufficiently function as an insulation film. Specifically, the protective film is formed by a CVD method, over the entire surface of the first photodetector, by: arranging a container 30 having a circular or polygonal shape of an internal cross-section in a chamber 3, arranging an electrode 24 in the container 30; grounding one side of the container 30 and the electrode 24; accommodating the first photodetector in the container 30; supplying a raw material gas to the container 30, rotating or swinging the container 30 around a direction substantially perpendicular to the cross-section as a rotational axis and thereby moving the first photodetector in the container 30; supplying high-frequency power to the other side of the container 30 and the electrode 24; and generating a raw-material-gas-based plasma between the electrode 24 and the container 30.

<Second Photodetector as Electronic Component>

The second photodetector of an exemplary electronic component according to an aspect of the invention has the base body 101a as illustrated in FIG. 1B, a plurality of elements 102 and a wiring 103 interconnecting the plurality of elements 102 are formed on the base body 101a.

A protective film (not illustrated) is formed over the entire surface of the second photodetector. The protective film is similar to the protective film of the first photodetector of the present embodiment.

<Ball-Shaped Solar Cell as Electronic Component>

The ball-shaped solar cell of an exemplary electronic component according to an aspect of the invention has the spherical base body 101b as illustrated in FIG. 2A, and a solar cell element and a wiring 103b are formed on the base body 101b.

A protective film (not illustrated) is formed over the entire surface of the ball-shaped solar cell 104. The protective film is similar to the protective film of the first photodetector of the present embodiment.

<Semiconductor Chip as Electronic Component>

The Semiconductor chip of an exemplary electronic component according to an aspect of the invention has a Cu wiring (Cu alloy wiring) 103c formed on the silicon substrate 101c, as illustrated in FIGS. 3A and 3B. A SiO₂ film 106 is formed as a protective film over the entire surface of the semiconductor chip having the Cu wiring 103c.

Note that, although the SiO₂ film 106 is formed as a protective film in the present aspect, a DLC film may be formed as a protective film.

The above-described protective film is a film formed by the plasma processing apparatus illustrated in FIG. 5, and has high insulation characteristics so as to sufficiently function as an insulation film. Specifically, the protective film is formed by a CVD method, over the entire surface of the semiconductor chip, by: arranging a container 30 having a circular or polygonal internal cross-sectional shape in a chamber 3, arranging an electrode 24 in the container 30; grounding one side of the container 30 and the electrode 24; accommodating the semiconductor chip in the container 30; supplying a raw material gas to the container 30, rotating or swinging the container 30 around a direction substantially perpendicular to the cross-section as a rotational axis and thereby moving the semiconductor chip in the container 30; supplying high-frequency power to the other side of the container 30 and the electrode 24; and generating a raw-material-gas-based plasma between the electrode 24 and the container 30.

<Plasma Processing Apparatus>

FIG. 5A is a cross-sectional view illustrating the outline of a plasma processing apparatus according to an aspect of the invention, and FIG. 5B is a cross-sectional view taken along the line 8B-8B illustrated in FIG. 5A.

The plasma processing apparatus is an apparatus for forming a thin film (protective film) over the entire surface of the electronic component by a CVD method, or for etching the entire surface of electronic component.

The plasma processing apparatus has a cylindrical chamber 3. Both ends of the chamber 3 are closed by the chamber lid 20. A container 30 is arranged in the interior of the chamber 3. The container 30 has a hexagonal-barrel-shaped section (hexagonal barrel shape) as illustrated in FIG. 5B, and the electronic component 100 is accommodated in the container 30. In addition, the container 30 also functions as an electrode and is connected to a plasma power source 131 or ground potential, the both being constituted to be switchable by a switch 32. The cross-section illustrated in FIG. 5B is a cross-section substantially parallel to the direction of gravity. Note that, although the hexagonal-barrel-shaped container 30 is used in the present embodiment, the invention is not limited thereto and a container having a polygonal barrel shape other than a hexagonal barrel shape can also be used, or a container having a substantially circular cross-sectional shape or a container having a substantially oval cross-sectional shape can also be used.

The container 30 has a rotation mechanism (not illustrated) provided therein, and the film forming treatment is performed while stirring or rotating the electronic component 100 in the container 30 by rotating, as indicated by the arrow, the container 30, with the gas shower electrode 24 as a center of rotation, through the use of the rotation mechanism. The axis of rotation when rotating the container 30 through the use of the rotation mechanism is an axis parallel to a substantially horizontal direction (substantially perpendicular to the direction of gravity). In addition, the airtightness inside the chamber 3 is maintained at the time of rotation of the container 30.

In addition, the plasma processing apparatus has a gas introduction mechanism configured to introduce a raw material gas or an etching gas into the chamber 3. The gas introduction mechanism has a cylindrical gas shower electrode 24, and the gas shower electrode 24 is arranged in the container 30. Namely, an aperture is formed on one side of the container 30, and the gas shower electrode 24 is inserted through the aperture. The gas shower electrode 24 has a plurality of gas outlets configured to eject, in a shower-like state, one or more types of raw material gases or etching gases. The gas outlets are arranged so as to face the electronic component 100 accommodated in the container. The gas outlets are arranged in the direction of rotation of the container 30 at an angle of approximately 1° to 90° against the direction of gravity, as illustrated in FIG. 5B.

The gas shower electrode 24 is connected (not illustrated) to the raw material gas source or the etching gas source via a vacuum valve, a mass flow controller (MFC), a vacuum valve, a filter, or the like. The raw material gas source generates different types of raw material gases depending on the thin film (protective film) to be formed on the electronic component 100, and is assumed to generate SiH₄ gas or the like when forming, for example, a SiO₂ film.

In addition, the plasma processing apparatus includes a plasma power supply mechanism, and the plasma power supply mechanism has a plasma power source 25 connected to the gas shower electrode 24 via a switch 33. It is sufficient that the plasma power sources 25 and 131 are any of a high-frequency power source that supplies high-frequency power (RF output), a microwave power source, a DC discharge power source, as well as a high-frequency power source, a microwave power source, and a DC discharge power source, each of which being pulse-modulated. When, for example, the plasma power source is one that supplies high-frequency power, it is preferable to arrange, between the high-frequency power source and the gas shower electrode 24, an impedance matching device (matching box) which is not illustrated. Namely, in this case, the gas shower electrode 24 is connected to the matching box, and the matching box is connected to the high-frequency power source (RF source) via a coaxial cable.

Note that the plasma power source may be connected to one of the gas shower electrode 24 and the container 30, with the ground potential being connected to the other, or the plasma power source may be connected to both of the gas shower electrode 24 and the container 30.

In addition, the plasma processing apparatus includes a vacuum exhaust mechanism that vacuum-exhausts the chamber 3. For example, a plurality of exhaust ports (not illustrated) that exhausts the interior of the chamber 3 is provided in the gas shower electrode 24, and each of the exhaust ports is connected to a vacuum pump (not illustrated).

<Method of Manufacturing Electronic Component>

A method of forming a protective film on the electronic component 100 by using the plasma processing apparatus illustrated in FIG. 5 will be described. Here, there will be described an exemplary method of using, as the electronic component 100, the first photodetector illustrated in FIG. 1A, the second photodetector illustrated in FIG. 1B, the ball-shaped solar cell illustrated in FIG. 2, the semiconductor chip illustrated in FIG. 3, or the like, and of using a protective film (e.g., SiO₂ film, DLC film, etc.) on the electronic component 100.

First, a plurality of the electronic components 100 is accommodated in the container 30. The maximum external diameter of each of the electronic components 100 is 50 mm or less (preferably 5 mm or less).

Subsequently, the interior of the chamber 3 is decompressed to a predetermined pressure (e.g., about 2×10³ Torr) by operating a vacuum pump. At the same time, rotation of the container 30 by the rotation mechanism causes the electronic component 100 accommodated therein to move on the internal surface of the container 30 while rolling between the direction of gravity and a direction 90° against the direction of gravity in the direction of rotation. Although the chamber 3 is being rotated here, the chamber 3 may be caused to swing by the rotation mechanism.

Next, a raw material gas (e.g., SiH₄ gas) is generated in the raw material gas source, the flow rate of the raw material gas is controlled by the mass flow controller, and the flow-rate-controlled raw material gas is introduced into the interior of the gas shower electrode 24. Then, the raw material gas is then ejected from the gas outlets of the gas shower electrode. Accordingly, a raw material gas is sprayed on the electronic component 100 rolling and moving in the container 30, and the interior of the container 30 is kept at a pressure suitable for film formation by a CVD method due to the balance between the controlled gas flow rate and the exhaust ability.

Subsequently, an RF output of 13.56 MHz is supplied from a high-frequency power source (RF source) that is an exemplary plasma power source 25, to the gas shower electrode 24 via the matching box, for example. In this case, the container 30 is connected to the ground potential. Accordingly, plasma is ignited between the gas shower electrode 24 and the container 30. At this time, the matching box is matched with the impedance of the container 30 and the gas shower electrode 24 on the basis of the inductance L and the capacitance C. Accordingly, plasma is generated in the container 30, whereby a protective film containing SiO₂ is formed over the entire surface of the electronic component 100. Namely, the electronic component 100 is rolled by rotating the container 30, and thus the protective film can be formed with a good uniformity over the entire surface of the electronic component 100.

According to the present embodiment, rotation of the hexagonal-barrel-shaped container 30 itself allows the electronic component 100 itself to be rotated and stirred, and the hexagonal shape of the barrel further allows the electronic component 100 to regularly drop by gravity. Therefore, it becomes possible to form a protective film with a good uniformity on the electronic component having a very small external diameter.

Note that, although a plasma CVD method of forming a protective film including SiO₂ on the electronic component 100 is described in the above-described embodiment, a plasma processing apparatus according to the present embodiment can be used for forming a protective film including materials other than a SiO₂ film on the electronic component 100.

In addition, in the above-described embodiment, as to the formation of the protective film over the entire surface of the electronic component 100, the protective film may be formed over the entire surface of the electronic component 100 after having etched the entire surface of the electronic component 100 and having removed an unnecessary insulation film or the like, before forming the protective film over the entire surface of the electronic component 100. In this case, details of the manufacturing method will be given as follows.

An etching gas is generated in the etching gas source, the etching gas is controlled to be a predetermined flow rate by the mass flow controller, and the flow-rate-controlled etching gas is introduced into the interior of the gas shower electrode 24. Then, the etching gas is then ejected from the gas outlets of the gas shower electrode 24. Accordingly, the etching gas is sprayed on the electronic component 100 rotationally moving in the container 30, and the interior of the chamber 113 is kept at a pressure suitable for etching due to the balance between controlled gas flow rate and the exhaust ability.

Subsequently, an RF output is supplied from the power source 23 to the gas shower electrode 24. In this case, the chamber 113 and the electronic component 100 are grounded. Accordingly, plasma is ignited between the gas shower electrode 24 and the container 30, and plasma is generated in the container 30, with the result that the entire surface of the electronic component 100 is etched.

Next, a protective film is formed over the entire surface of the electronic component 100 by a method similar to the above-described method of forming the protective film by terminating supply of an etching gas, generating a raw material gas in the raw material gas source, controlling the flow rate of the raw material gas by the mass flow controller, controlling the flow rate of argon gas supplied from the argon gas cylinder, and introducing the flow-rate-controlled gas into the interior of the gas shower electrode 24.

### Embodiment 3

<First Photodetector as Electronic Component>

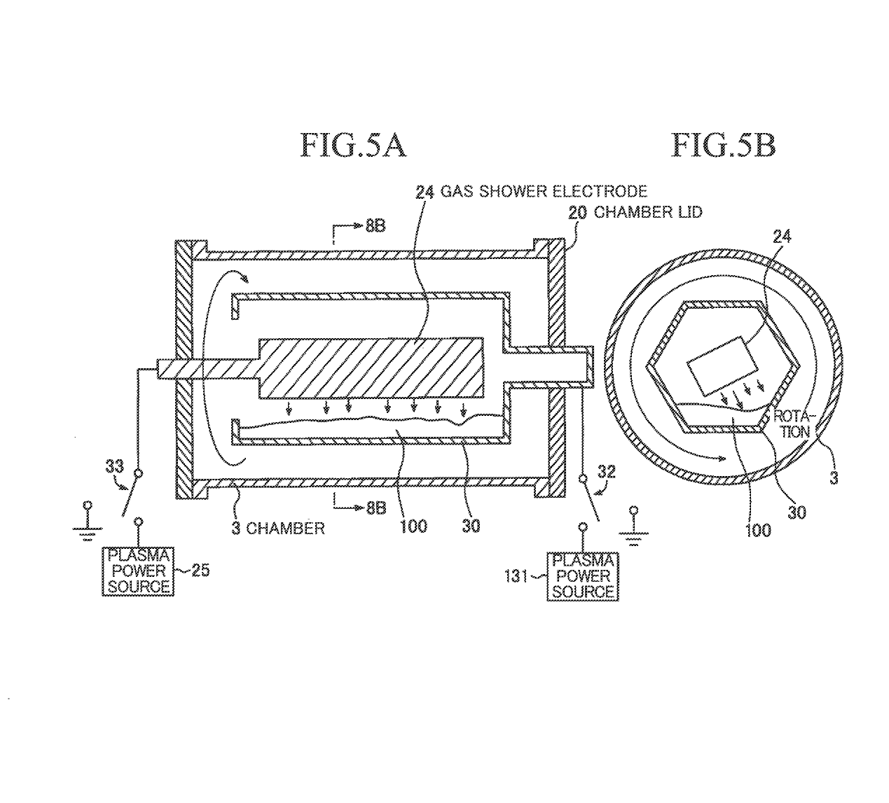

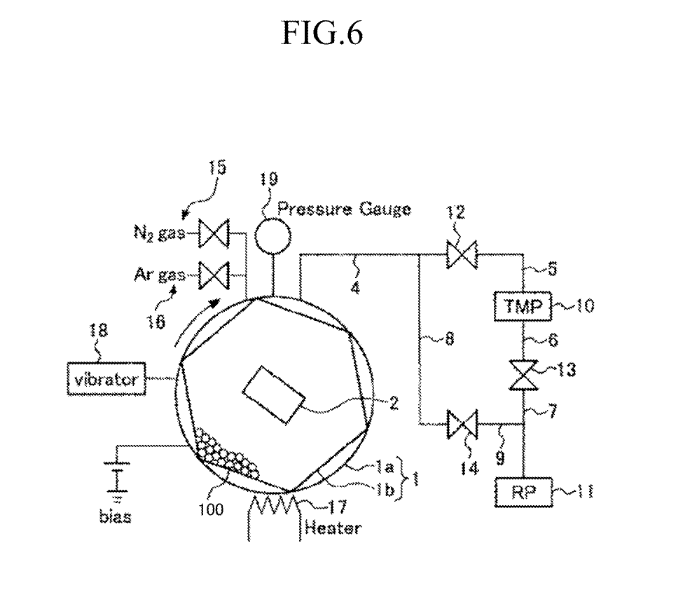

The first photodetector of an exemplary electronic component according to an aspect of the invention has an element 102 and a wiring 103 formed on the base body 101 as illustrated in FIG. 1A. A protective film (not illustrated) is formed over the entire surface of the first photodetector. The protective film is a film formed by the sputtering apparatus illustrated in FIG. 6, and is specifically formed over the entire surface of the first photodetector by: accommodating the first photodetector in the chamber 1 having a circular or polygonal shape of an internal cross-section, and rotating or swinging the chamber 1 around a direction substantially perpendicular to the cross-section as a rotational axis and thereby performing sputtering while stirring or rotating the first photodetector in the chamber 1.

<Second Photodetector as Electronic Component>

The second photodetector of an exemplary electronic component according to an aspect of the invention has a base body 101a as illustrated in FIG. 1B, a plurality of elements 102 and a wiring 103 interconnecting the plurality of elements 102 are formed on the base body 101a.

A protective film (not illustrated) is formed over the entire surface of the second photodetector. The protective film is similar to the protective film of the first photodetector of the present embodiment.

<Ball-Shaped Solar Cell as Electronic Bomponent>

The ball-shaped solar cell of an exemplary electronic component according to an aspect of the invention has the spherical base body 101b as illustrated in FIG. 2A, and a solar cell element and wiring 103b are formed on the base body 101b.

A protective film (not illustrated) is formed over the entire surface of the ball-shaped solar cell 104. The protective film is similar to the protective film of the first photodetector of the present embodiment.

<Semiconductor Chip as Electronic Component>

The semiconductor chip of an exemplary electronic component according to an aspect of the invention has a Cu wiring (Cu alloy wiring) 103c formed on the silicon substrate 101c, as illustrated in FIGS. 3A and 3B. A SiO₂ film 106 is formed as a protective film over the entire surface of the semiconductor chip having the Cu wiring 103c.

Note that, although the SiO₂ film 106 is formed as a protective film in the present aspect, a DLC film may be formed as a protective film.

The above-described protective film having formed by the sputtering apparatus illustrated in FIG. 6 has high insulation characteristics so as to sufficiently function as an insulation film. Specifically, the protective film is formed over the entire surface of the semiconductor chip, by: accommodating the semiconductor chip in the chamber 1 having a circular or polygonal shape of an internal cross-section, and rotating or swinging the chamber 1 around a direction substantially perpendicular to the cross-section as a rotational axis and thereby performing sputtering while stirring or rotating the first photodetector in the chamber 1.

<Sputtering Device>

FIG. 6 is a configuration diagram outlining a sputtering apparatus according to an aspect of the invention. The sputtering apparatus is an apparatus that forms a thin film (protective film) over the entire surface of the electronic component by sputtering.

The sputtering apparatus has the chamber 1 that forms a thin film (protective film) on the electronic component 100, and the chamber 1 includes a cylindrical part 1a having a diameter of 200 mm and a barrel having a cross-section of hexagon (hexagonal barrel) 1b provided therein. The cross-section illustrated here is a cross-section substantially parallel to the direction of gravity. Although the hexagonal barrel 1b is used in the present embodiment, the invention is not limited thereto and any polygonal barrel other than a hexagonal barrel can also be used, or a circular or oval barrel can also be used.

A rotation mechanism (not illustrated) is provided in the chamber 1, and the film forming treatment is performed while stirring or rotating the electronic component 100 in the hexagonal barrel 1b by rotating the hexagonal barrel 1b, as indicated by the arrow, by the rotation mechanism. The axis of rotation when rotating the hexagonal barrel by the rotation mechanism is an axis parallel to a substantially horizontal direction (perpendicular to the direction of gravity). In addition, a sputtering target 2 is provided on the central axis of the cylinder in the chamber 1, and the sputtering target 2 is a target including materials of a thin film to be formed. In addition, the target 2 is constituted so that its angle can be freely changed. Accordingly, when performing the film formation process while rotating the hexagonal barrel 1b, the target 2 can be oriented to the direction in which the electronic component 100 is positioned, thereby making it possible to increase the sputtering efficiency.

One end of a plumbing 4 is connected to the chamber 1, and one side of a first valve 12 is connected to the other end of the plumbing 4. One end of a plumbing 5 is connected to the other side of the first valve 12, and the other end of the plumbing 5 is connected to the intake side of a turbo molecular pump (TMP) 10. The exhaust side of the turbo molecular pump 10 is connected to one end of a plumbing 6, and the other end of the plumbing 6 is connected to one side of a second valve 13. The other side of the second valve 13 is connected to one end of a plumbing 7, and the other end of the plumbing 7 is connected to a pump (RP) 11. In addition, the plumbing 4 is connected to one end of a plumbing 8, and the other end of the plumbing 8 is connected to one side of a third valve 14. The other side of the third valve 14 is connected to one end of a plumbing 9, and the another end of the plumbing 9 is connected to the plumbing 7.

The apparatus includes a heater 17 for heating the electronic component 100 in the chamber 1. In addition, the apparatus includes a vibrator 18 for applying vibration to the electronic component 100 in the chamber 1. Additionally, the apparatus includes a pressure gauge 19 for measuring the internal pressure of chamber 1. Furthermore, the apparatus includes a nitrogen gas introduction mechanism 15 that introduces a nitrogen gas into the chamber 1, and also an argon gas introduction mechanism 16 that introduces argon gas into the chamber 1. Moreover, the apparatus includes a high-frequency application mechanism (not illustrated) that applies a high-frequency between the target 2 and the hexagonal barrel 1b.

<Method of Manufacturing Electronic Component>

A method of forming a protective film on the electronic component 100 by using the sputtering apparatus illustrated in FIG. 6 will be described. Here, there will be described an exemplary method of using, as the electronic component 100, the first photodetector illustrated in FIG. 1A, the second photodetector illustrated in FIG. 1B, the ball-shaped solar cell illustrated in FIG. 2, the semiconductor chip illustrated in FIG. 3, or the like, and of using a protective film (e.g., SiO₂ film, DLC film, etc.) on the electronic component 100.

First, a plurality of the electronic components 100 is accommodated in the hexagonal barrel 1b. The maximum external diameter of each of the electronic components 100 is 50 mm or less (preferably 5 mm or less). In addition, SiO₂ is used as the target 2. Note that, although SiO₂ is used as the target 2 in the present embodiment, the invention is not limited thereto and other material such as a target including DLC can also be used.

Next, a high vacuum state is created inside the hexagonal barrel 1b by using the turbo molecular pump 10, and the interior of the hexagonal barrel is decompressed to a predetermined pressure while the hexagonal barrel is heated by the heater 17. Subsequently, an inert gas such as argon or nitrogen is introduced into the hexagonal barrel 1b by an argon gas introduction mechanism 16 or a nitrogen gas introduction mechanism 15. In addition, the electronic component 100 in the hexagonal barrel 1b is then rotated and stirred by rotating the hexagonal barrel 1b by rotation mechanism for 30 minutes at 100 W and at the speed of 20 rpm. In this case, the target is oriented to a direction in which the electronic component 100 is positioned. Subsequently, SiO₂ is sputtered on the surface of the electronic component 100 by applying a high-frequency between the target 2 and the hexagonal barrel 1b by high-frequency application mechanism. In this way, a thin film (protective film) can be formed over the entire surface of the electronic component 100.

According to the present embodiment, rotation of the hexagonal barrel itself allows the electronic component itself to be rotated and stirred, and the hexagonal shape of the barrel allows the electronic component to regularly drop by gravity. Accordingly, the stirring efficiency can be drastically enhanced. Therefore, it becomes possible to form a thin film (protective film) on the electronic component having a very small external diameter.

In addition, in the present embodiment, the heater 17 is attached to the outside of the chamber 1, and is capable of heating the hexagonal barrel 1b. Therefore, moisture in the hexagonal barrel can be vaporized and exhausted by heating the hexagonal barrel by the heater 17, in vacuuming the interior of the chamber 1.

Additionally, in the present embodiment, the vibrator 18 is attached to the outside of the chamber 1, and is capable of applying vibration to the electronic component 100 in the hexagonal barrel.

Note that, although vibration is applied to the electronic component 100 in the hexagonal barrel by the vibrator 18 in the present embodiment, vibration may also be applied to the electronic component 100 by rotating the hexagonal barrel in a state where a rod-like member is accommodated in the hexagonal barrel, in place of the vibrator 18 or in addition to the vibrator 18.

Furthermore, as to the formation of the protective film over the entire surface of the electronic component 100 in the present embodiment, the protective film may be formed over the entire surface of the electronic component 100 after having etched the entire surface of the electronic component 100 and then having removed an unnecessary insulation film or the like, before forming the protective film over the entire surface of the electronic component 100.

Note that the above-described embodiments 1 to 3 may be implemented in combination as necessary.

### EXAMPLES

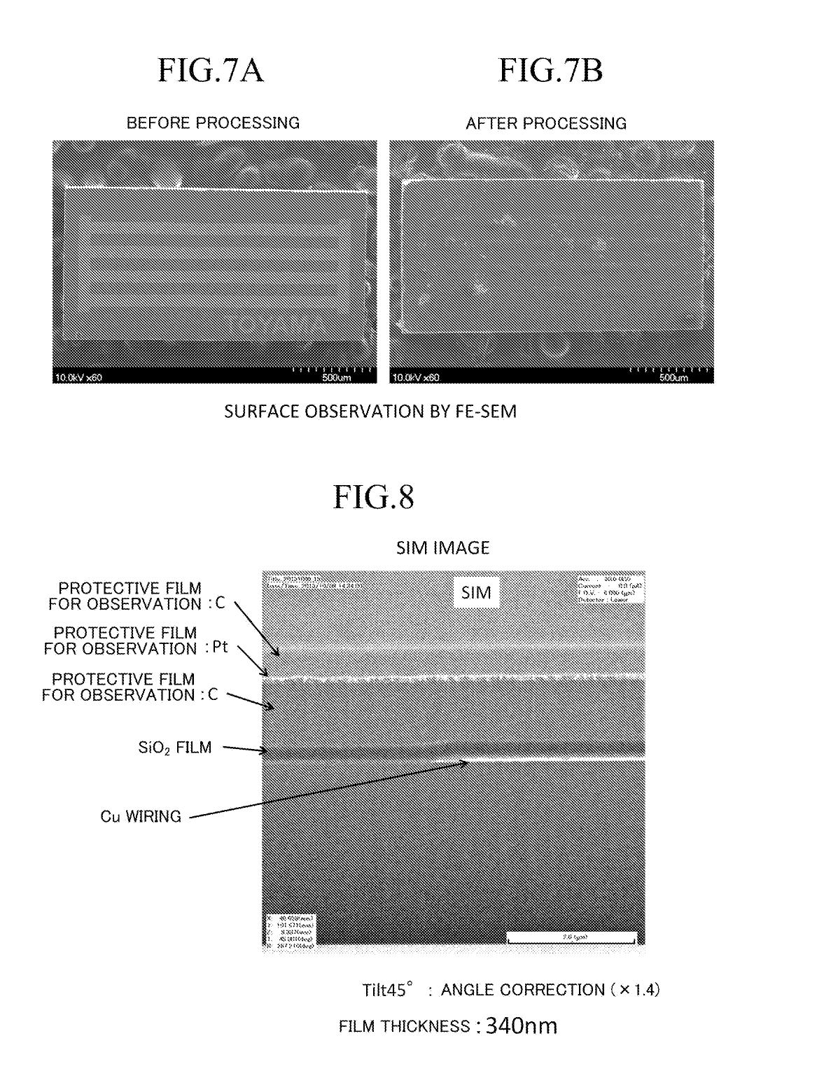

FIG. 7A is an FE-SEM (Field Emission Scanning Electron Microscope) image obtained by observing the surface of a semiconductor chip before forming (before processing) an SiO₂ film over the entire surface as a protective film, and FIG. 7B is an FE-SEM image obtained by observing the surface of the semiconductor chip after having formed (after processing) the SiO₂ film over the entire surface as the protective film. FIG. 8 is a SIM (Scanning Ion Microscopy) image obtained by observing a cross-section of the semiconductor chip having formed thereon the protective film illustrated in FIG. 7B.

The semiconductor chip illustrated in FIG. 7A has been obtained by forming a Cu film on a silicon wafer by sputtering, patterning the Cu film to thereby form a Cu wiring, and cutting the silicon wafer into semiconductor chips by dicing, and is in a state before forming the SiO₂ film illustrated in FIG. 8.

The semiconductor chip illustrated in FIG. 7B has been obtained by forming an SiO₂ film as a protective film over the entire surface of the semiconductor chip illustrated in FIG. 7A by using the plasma CVD device illustrated in FIG. 5 under the film-forming condition shown in table 1, and has a film structure similar to that in FIG. 3B. Namely, the semiconductor chip corresponds to a state before forming the protective film for observation shown in FIG. 8. Note that the raw material gas HMDS-N shown in table 1 refers to HMDS (hexamethyldisilazane) that contains nitrogen.

The semiconductor chip illustrated in FIG. 8 is obtained by sequentially forming a carbon (C) film, a Pt film, and a carbon (C) film as protective films for observation, on the SiO₂ film of the semiconductor chip illustrated in FIG. 7B. The protective film for observation is a film for protecting the semiconductor chip when observing a section of the semiconductor chip illustrated in FIG. 7B, with SIM. According to FIG. 8, the thickness of the SiO₂ film is 340 nm.

TABLE 1
FILM FORMING CONDITION
BASIC FILM FORMING CONDITION - A3

| | | |
|---|---|---|
| HMDS-N | 6 | cc/min |
| O₂ | 120 | cc/min |
| RF OUTPUT | 250 | w |
| TEMPERATURE | 100 | ° C. |
| PRESSURE | 17 | Pa |
| TIME | 30 | min |

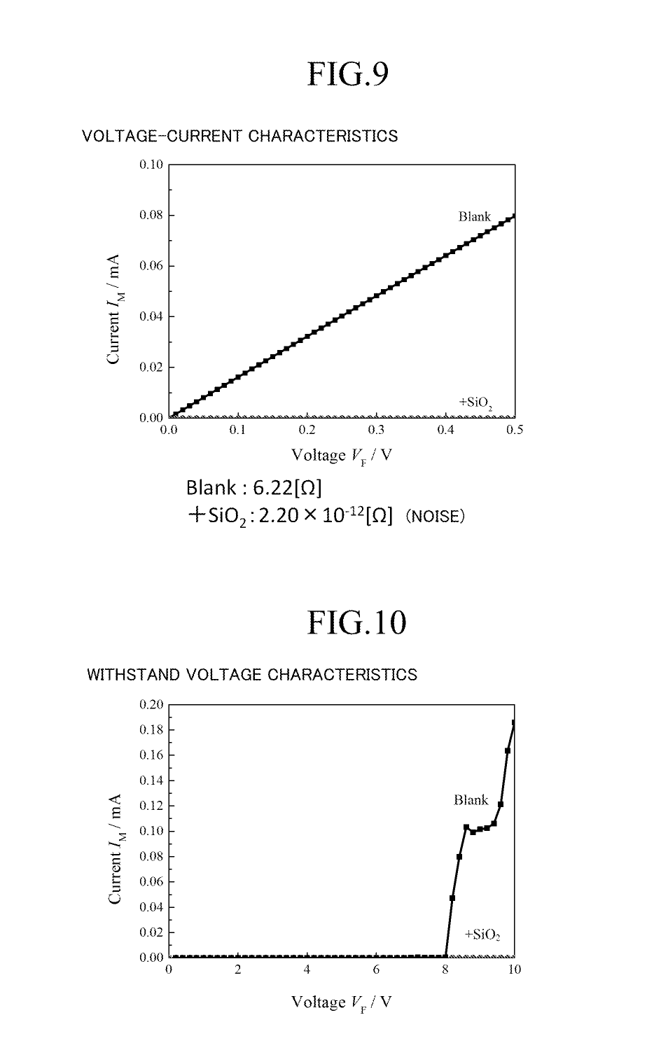

FIG. 9 illustrates an experimental result obtained by examining whether or not the SiO₂ film on the semiconductor chip illustrated in FIG. 7B has sufficient insulation characteristics, and is a graph indicating the voltage-current characteristics.

“Blank” illustrated in FIG. 9 indicates, for comparison, a result obtained by applying a probe onto the top left end and the bottom right of the Cu wiring of the “BlankTip” which is the semiconductor chip illustrated in FIG. 7A, applying voltage by the semiconductor parameter analyzer and measuring the generated current. The resistance value of the Cu wiring turned out to be 6.22Ω from the measurement result.

In contrast, “+SiO₂” (Tip-with-SiO₂-film) illustrated in FIG. 9 indicates a result of measuring a generated current by applying voltage to a position (between the top left end and the bottom right end of the Cu wiring) corresponding to the above-described “BlankTip” in the SiO₂ film of the semiconductor chip illustrated in FIG. 7B. It has been proved from the measurement result that the SiO₂ film has sufficient insulation characteristics and sufficiently functions as an insulation film.

FIG. 10 illustrates an experimental result obtained by examining whether or not the SiO₂ film as the protective film of semiconductor chip illustrated in FIG. 7B has sufficient withstand voltage characteristics, and is a graph indicating the relation between voltage and current.

For comparison, there is illustrated in FIG. 10 a result of applying a probe onto the silicon part at the top left end and the silicon part at the bottom right end where no Cu wiring is formed, of the “BlankTip” which is the semiconductor chip illustrated in FIG. 7A, and measuring a generated current by applying voltage by the semiconductor parameter analyzer. As illustrated in FIG. 10, the “BlankTip” has turned completely conductive at 8 V and thereafter.

In contrast, there is illustrated in FIG. 10 a result of applying a probe onto a position (the silicon part at the top left end and the silicon part at the bottom right end where no Cu wiring is formed) corresponding to the above-described “BlankTip” in the SiO₂ film of the Tip-with-SiO₂-film which is the semiconductor chip illustrated in FIG. 7B, and measuring a generated current by applying voltage by the semiconductor parameter analyzer. As illustrated in FIG. 10, the SiO₂ film of the Tip-with-SiO₂-film maintains insulation up to 10 V, and keeps maintaining insulation without being conductive even when the applied voltage is increased up to 100 V. It has been proved from the measurement result that the SiO₂ film has sufficient withstand voltage characteristics and sufficiently functions as an insulation film.

### DENOTATION OF REFERENCE NUMERALS

1 chamber
1a cylindrical part
1b barrel having a cross-section of hexagon (hexagonal barrel)
2 sputtering target
3 chamber
5, 6, 7, 8, 9 plumbing
10 turbo molecular pump
11 pump (RP)
12 first valve
13 second valve
14 third valve
15 nitrogen gas introduction mechanism
16 argon gas introduction mechanism
17 heater
18 vibrator
19 pressure gauge
20, 21a, 21b chamber lid
20a raw material gas source
22 mass flow controller (MFC)
23 power source
24 gas shower electrode
25 plasma power source
26a, 26b vacuum valve
27a ground shielding member
29 motor
30 container
31 arrow
32, 33 switch
100 electronic component
101, 101a, 101b base body
101c silicon substrate
102 element
103, 103b wiring
103c Cu wiring (Cu alloy wiring)
104 ball-shaped solar cell
105 substrate
106 SiO₂ film
111 direction of gravity
113 chamber
131 plasma power source

1. An electronic component having a protective film formed over the entire surface thereof,
wherein said electronic component has elements and wirings formed on a base body,
wherein said protective film has been formed by a CVD method, over an entire surface of said electronic component, by: arranging an electrode in a chamber; grounding one side of said chamber and said electrode; accommodating said electronic component in said chamber; supplying a raw material gas to said chamber; rotating or swinging said chamber and thereby moving said electronic component in said chamber; supplying high-frequency power to the other side of said chamber and said electrode; and generating a raw-material-gas-based plasma between said electrode and said chamber.

2. An electronic component having a protective film formed over the entire surface thereof,
wherein said electronic component has elements and wirings formed on a base body,
wherein said protective film has been formed by a CVD method, over an entire surface of said electronic component, by: arranging, in a chamber, a container having a circular or polygonal shape of an internal cross-section; arranging an electrode in said container; grounding one side of said container and said electrode; accommodating said electronic component in said container; supplying a raw material gas to said container; rotating or swinging said container around a direction substantially perpendicular to said cross-section as a rotational axis and thereby moving said electronic component in said container; supplying high-frequency power to the other side of said container and said electrode; and generating a raw-material-gas-based plasma between said electrode and said container.

3. An electronic component having a protective film formed over the entire surface thereof,
wherein said electronic component has elements and wirings formed on a base body,
wherein said protective film has been formed over an entire surface of said electronic component by: accommodating said electronic component in a chamber having a circular or polygonal shape of an internal cross-section; rotating or swinging said chamber around a direction substantially perpendicular to said cross-section as a rotational axis and thereby performing sputtering while stirring or rotating said electronic component in said chamber.

4. The electronic component according to claim 1, wherein said element is an optical sensor.

5. The electronic component according to claim 1, wherein said element is a solar cell element.

6. The electronic component according to claim 5, wherein said base body contains amorphous silicon or polycrystalline silicon.

7. A method of manufacturing an electronic component, comprising the steps of: arranging an electrode in a chamber; grounding one side of said chamber and said electrode; accommodating, in said chamber, an electronic component having elements and wirings formed on a base body; supplying a raw material gas to said chamber; rotating or swinging said chamber and thereby moving said electronic component in said chamber; supplying high-frequency power to the other side of said chamber and said electrode; and generating a raw-material-gas-based plasma between said electrode and said chamber to thereby form a protective film over an entire surface of said electronic component, by a CVD method.

8. The method of manufacturing an electronic component according to claim 7 comprising the steps of: supplying an etching gas to said chamber before supplying a raw material gas to said chamber; etching an entire surface of said electronic component by generating etching gas-based plasma between said electrode and said chamber and then terminating supply of said etching gas to said chamber; and supplying said raw material gas to said chamber.

9. A method of manufacturing an electronic component, comprising the steps of: arranging in a chamber a container having a circular or polygonal shape of an internal cross-section; arranging an electrode in said container; grounding one side of said container and said electrode; accommodating, in said container, said electronic component having elements and wirings formed on a base body; supplying a raw material gas to the container; rotating or swinging said container around a direction substantially perpendicular to said cross-section as a rotational axis and thereby moving said electronic component in said container; supplying high-frequency power to the other side of said container and said electrode; and generating a raw-material-gas-based plasma between said electrode and said container to thereby form a protective film over an entire surface of said electronic component, by a CVD method.

10. The method of manufacturing an electronic component according to claim 9 comprising the steps of: supplying an etching gas to said container before supplying a raw material gas to said container; etching the entire surface of said electronic component by generating an etching gas-based plasma between said electrode and said container and then terminating supply of said etching gas to said container; and supplying said raw material gas to said container.

11. The method of manufacturing an electronic component according to claim 7, wherein a frequency of said high-frequency power is in a range of 10 kHz to 1 MHz.

12. The method of manufacturing an electronic component according to claim 7, wherein said element is an optical sensor.

13. The method of manufacturing an electronic component according to claim 7, wherein said element is a solar cell element.

14. The method of manufacturing an electronic component according to claim 13, wherein said base body contains amorphous silicon or polycrystalline silicon.
